(19) United States
(12) Patent Application Publication
(10) Pub. No.: US 2016/0230272 A1
(43) Pub. Date: Aug. 11, 2016

(54) EVAPORATION SOURCE HEATING DEVICE

(71) Applicant: SHENZHEN CHINA STAR OPTOELECTRONICS TECHNOLOGY CO. LTD., Shenzhen, Guangdong (CN)

(72) Inventor: Qinghua ZOU, Shenzhen, Guangdong (CN)

(73) Assignee: Shenzhen China Star Optoelectronics Technology Co. Ltd., Shenzhen, Guangdong (CN)

(21) Appl. No.: 14/381,201

(22) PCT Filed: Jun. 12, 2014
(86) PCT No.: PCT/CN2014/079709

§ 371 Date: Aug. 26, 2014

(30) Foreign Application Priority Data
May 28, 2014 (CN) 201410231511.4

(51) Int. Cl. C23C 16/02; C23C 16/448

(52) U.S. Cl. CPC C23C 16/0209; C23C 16/448

(57) ABSTRACT

The present invention provides an evaporation source heating device, which includes: a base, a housing coupled to the base, a heating element arranged inside the housing, a plurality of metal barrels arranged inside the heating element and mounted to the base, and a crucible arranged inside the metal barrels. The evaporation source heating device according to the present invention is structured to set the plurality of metal barrels between the heating element and the crucible and the plurality of metal barrels is mounted to the base, whereby during heating, through a process of transmitting the heat from the heating element through the plurality of metal barrels in a step by step manner, the heat is transmitted to the crucible. Since the metal barrels have excellent properties of heat conduction, distribution of heat thereon is generally uniform, allowing the crucible to be uniformly heated and ensuring the result of evaporation deposition.

### BACKGROUND OF THE INVENTION

1. Field of the Invention

The present invention relates to the field of manufacture of organic electroluminescent devices, and in particular to an evaporation source heating device.

2. The Related Arts

An organic electroluminescent device is a self-luminous device, which has advantages, including low voltage, wide view angle, fast response, and good temperature adaptation and is believed to be of great prospects of application among flat panel displays and is even considered the next flat panel displaying technology succeeding to plasma display panels (PDPs) and liquid crystal displays (LCDs).

Based on the molecular weights of the organic electroluminescent materials used, the organic electroluminescent devices are classified as small molecule organic electroluminescent devices (such as organic light-emitting diode, OLED) and large molecule organic electroluminescent devices (such as polymer light-emitting diode, PLED). Due the difference in molecular weight, the two kinds of organic electroluminescent devices are of manufacturing processes that are quite different. OLED is generally made through a thermal evaporation process, while PLED is made through a spin-coating or inkjet printing process.

An OLED generally comprises a substrate, an ITO based transparent anode formed on the substrate, a hole injection layer (HIL) formed on the transparent anode, a hole transport layer (HTL) formed on the hole injection layer, an emissive layer (EML) formed on the hole transport layer, an electron transport layer (ETL) formed on the emissive layer, an electron injection layer (EIL) formed on the electron transport layer, and a cathode formed on the electron injection layer. To increase efficiency, the emissive layer generally adopts a host/guest doping system.

The manufacture process of OLED is thermal evaporation, where an organic material is heated in a vacuum condition (E⁻⁵ pa), allowing a sublimating organic material or a melting organic material to vaporize in a high temperature and deposit on a substrate carrying a TFT (Thin-Film Transistor) structure or an anode structure. Heretofore, the mainstream evaporation sources include point evaporation source and line evaporation source. The point evaporation source is generally used in a pilot line or an early-stage mass production line. Since the material utilization and film thickness homogeneity achieved with a line evaporation source are superior to those of a point evaporation source, most of the recently established mass production lines adopt line evaporation sources. However, the point evaporation source occupies a small amount of space and a number of point evaporation sources can be arranged in a single film-coating chamber, allowing deposition of a number of materials therein, thereby making it suitable for pilot lines.

The difference between the evaporation temperature and the decomposition temperature of an organic material is generally small. A crucible of a point evaporation source often has a great temperature difference in the interior thereof (top hot and bottom cold). If a great amount of material is deposited, the material is hard to reach a stable thermal balance condition, making the evaporation speed unstable. Increasing temperature to make the material thermally balance often cause potential risk of decomposition of the material in the top part. If the amount of material deposited is small, in a condition of high evaporation rate, the temperature of the upper part of the crucible often exceeds the decomposition temperature of the material, so that the vaporized material, when passing through this area, is susceptible to decomposition.

### SUMMARY OF THE INVENTION

An object of the present invention is to provide an evaporation source heating device, which comprises a plurality of metal barrels arranged between a heating element and a crucible so that through a process of transmitting heat from the heating element through the plurality of metal barrels in a step by step manner, the crucible is uniformly heated and the result of evaporation deposition is ensured.

To achieve the above object, the present invention provides an evaporation source heating device, which comprises: a base, a housing coupled to the base, a heating element arranged inside the housing, a plurality of metal barrels arranged inside the heating element and mounted to the base, and a crucible arranged inside the metal barrels.

The base is received in the housing and the base comprises a plurality of recesses formed therein. The plurality of metal barrels is respectively mounted in the plurality of recesses.

The metal barrels are cylindrical and the recesses are circular recesses.

The circular recesses are concentric.

The metal barrels have heights that are substantially equal to or less than a height of the housing.

The base is made of a metal or a thermal insulation ceramic material.

The metal barrels are made of metal plates.

The metal plates have thicknesses of 0.01 mm-10 cm.

The metal plates are made of materials of aluminum, aluminum alloys, titanium, titanium alloys, or materials having excellent thermal conductivities.

The heating element comprises a heating resistance wire.

The present invention also provides an evaporation source heating device, which comprises: a base, a housing coupled to the base, a heating element arranged inside the housing, a plurality of metal barrels arranged inside the heating element and mounted to the base, and a crucible arranged inside the metal barrels;

wherein the base is received in the housing and the base comprises a plurality of recesses formed therein, the plurality of metal barrels being respectively mounted in the plurality of recesses;

wherein the metal barrels are cylindrical and the recesses are circular recesses;

wherein the circular recesses are concentric;

wherein the metal barrels have heights that are substantially equal to or less than a height of the housing;

wherein the base is made of a metal or a thermal insulation ceramic material;

wherein the metal barrels are made of metal plates;

wherein the metal plates have thicknesses of 0.01 mm-10 cm;

wherein the metal plates are made of materials of aluminum, aluminum alloys, titanium, titanium alloys, or materials having excellent thermal conductivities; and

wherein the heating element comprises a heating resistance wire.

The efficacy of the present invention is that the present invention provides an evaporation source heating device, which comprises a plurality of metal barrels arranged between a heating element and a crucible. The plurality of metal barrels is mounted on a base. During heating, through a process of transmitting the heat from the heating element through the plurality of metal barrels in a step by step manner, the heat is transmitted to the crucible. Since the metal barrels have excellent properties of heat conduction, distribution of heat thereon is generally uniform, allowing the crucible to be uniformly heated and ensuring the result of evaporation deposition. Further, the number of the metal barrels can be increased or decreased according to practical needs in order to adjust the transfer and balance of temperature through the metal barrels and thus controlling the temperature difference of the crucible.

For better understanding of the features and technical contents of the present invention, reference will be made to the following detailed description of the present invention and the attached drawings. However, the drawings are provided for the purposes of reference and illustration and are not intended to impose undue limitations to the present invention.

### BRIEF DESCRIPTION OF THE DRAWINGS

The technical solution, as well as beneficial advantages, of the present invention will be apparent from the following detailed description of an embodiment of the present invention, with reference to the attached drawings. In the drawings:

FIG. 1 is a perspective view showing an evaporation source heating device according to an embodiment of the present invention;

FIG. 2 is a cross-sectional view showing the evaporation source heating device of FIG. 1;

FIG. 3 is a top plan view of a base of the evaporation source heating device of FIG. 1; and

FIG. 4 is a perspective view of the base of the evaporation source heating device of FIG. 1.

### DETAILED DESCRIPTION OF THE PREFERRED EMBODIMENTS

To further expound the technical solution adopted in the present invention and the advantages thereof, a detailed description is given to a preferred embodiment of the present invention and the attached drawings.

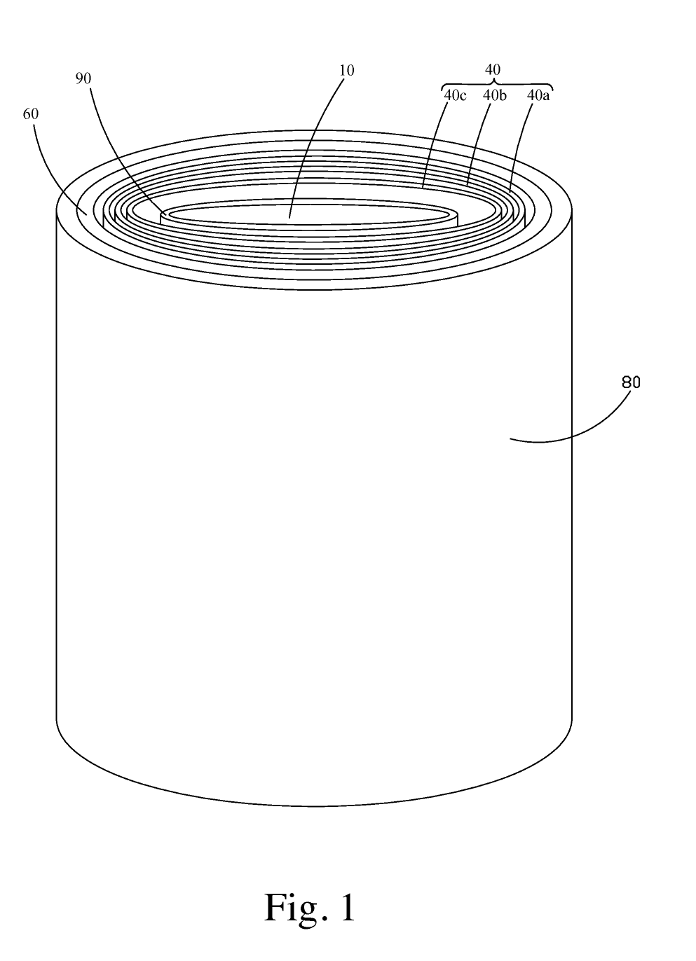

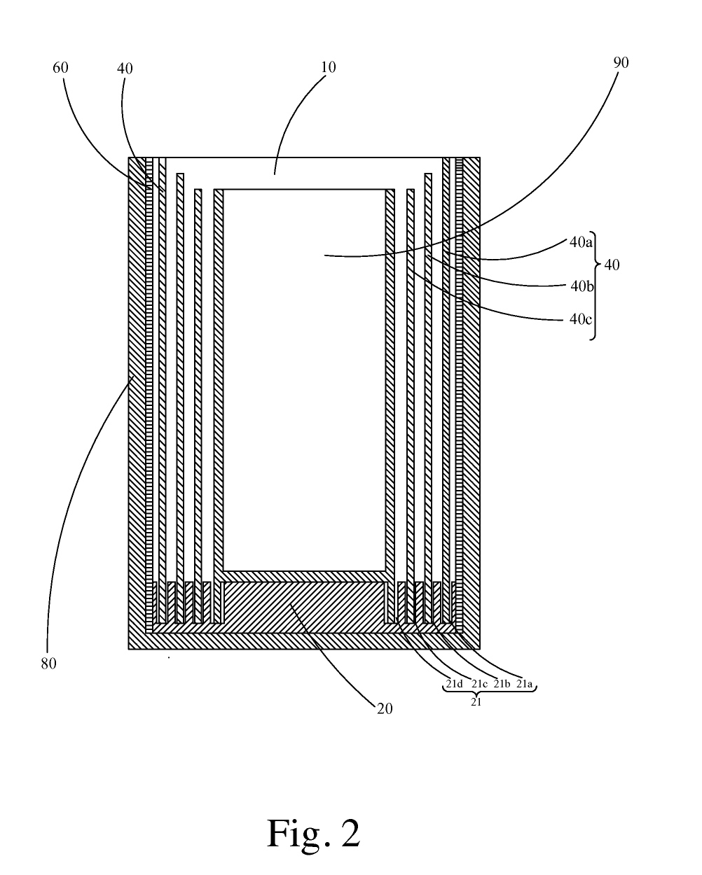

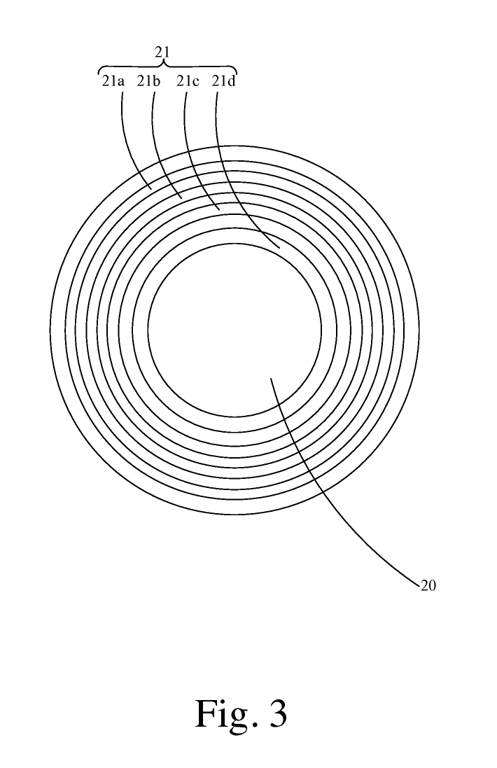

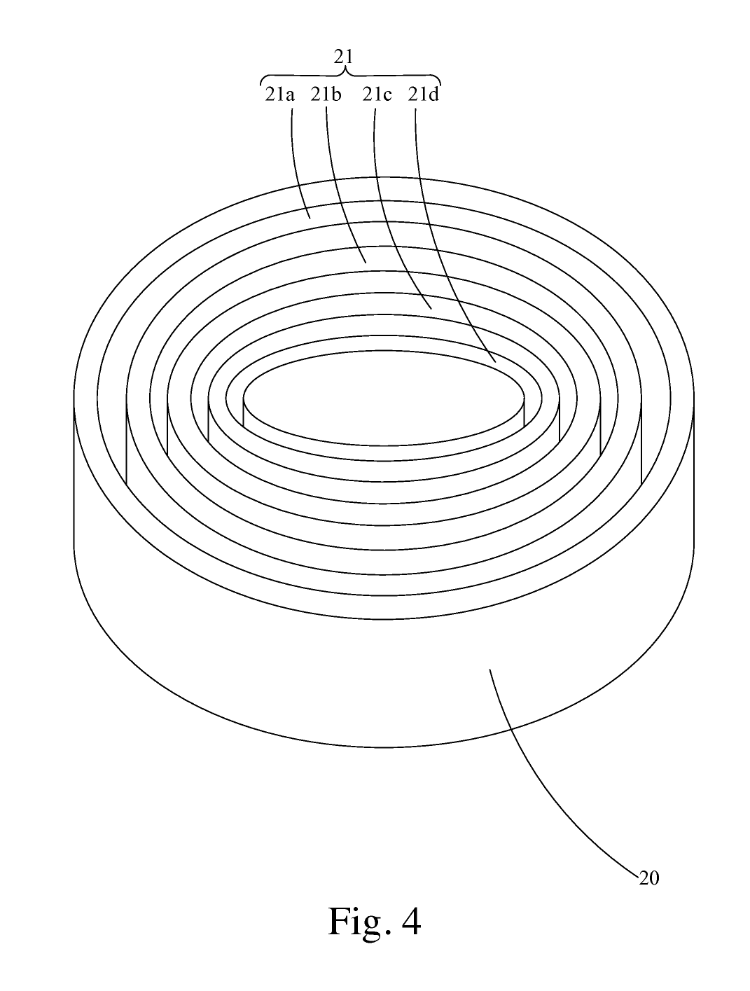

Referring to FIGS. 1-4, the present invention provides an evaporation source heating device 10, which comprises a base 20, a housing 80 coupled to the base 20, a heating element 60 arranged inside the housing 80, a plurality of metal barrels 40 arranged inside the heating element 60 and mounted to the base 20, and a crucible 90 arranged inside the metal barrels 40. The base 20 is received in the housing 80. The base 20 comprises a plurality of concentric circular recesses 21 formed therein. The metal barrels 40 are cylindrical barrels. The plurality of metal barrels 40 is respectively mounted in the plurality of recesses 21. The heating element 60 comprises a heating resistance wire.

In the instant embodiment, the base 20 comprises four concentric circular recesses 21, which are respectively designated 21a, 21b, 21c, and 21 d from the inside to the outside. The plurality of metal barrels 40 comprises three barrels, which are respective a first layer (the outermost layer) metal barrel 40a, a second layer (the middle layer) metal barrel 40b, and a third layer (the innermost layer) metal barrel 40c. The first-layer metal barrel 40a, the second-layer metal barrel 40b, and the third-layer metal barrel 40c are respectively mounted in the recesses 21a, 21b, and 21c. The crucible 90 is arranged at a center of the third-layer metal barrel 40c and is mounted in and located above the innermost recess 21d of the base 20. Further, according to the present invention, the number of the recesses 21 formed in the base 20 and the number of the metal barrels 40 mounted on the base 20 can be adjusted according to practical needs in order to achieve the best result of heating the crucible 90 contained in the evaporation source heating device 10.

When the heating element 60 starts heating, heat is transmitted through the first-layer metal barrel 40a to propagates step by step into the second-layer metal barrel 40b and the third-layer metal barrel 40c and then to the crucible 90 to achieve heating of the crucible 90. In a vacuum condition, the heat emitting from the heating element 60 of the evaporation source heating device 10 takes the form of thermal radiation that heats the metal barrels 40. Since the thermal energies emitting from different parts of the heating element 60 may be different, there may be a great temperature difference occurring in the first-layer metal barrel 40a. Due to the excellent thermal conductivity of metal, when the first-layer metal barrel 40a irradiates heat toward the second-layer metal barrel 40b, the thermal energy of a high temperature part thereof is also conducted to a low temperature part thereof so that the temperature difference between different parts of the first-layer metal barrel 40a becomes less and thus, the temperature difference that might occur in the second-layer metal barrel 40b may be even less. And, the difference of temperature in the third-layer metal barrel 40c is substantially zero. Thus, when the heat is transmitted to the crucible 90 that is located in the interior, the crucible 90 may receive the heat that shows substantially no temperature difference in different parts thereof so that the crucible 90 can be heated uniformly. In other words, with the arrangement of the metal barrels 40, the non-uniform distribution of heat from the heating element 60 is converted into heat of uniform distribution to be transmitted to the crucible 90, thereby achieving no temperature difference inside the crucible 90.

The metal barrels 40 may have heights that are substantially equal to or less than a height of the housing 80, allowing the metal barrels 40 not to project outside the housing 80. In the instant embodiment, the height of the first-layer metal barrel 40a is greater than a height of the crucible 90; the height of the second-layer metal barrel 40b is less than the height of the first-layer metal barrel 40a; and the height of the third-layer metal barrel 40c is less than the height of the second-layer metal barrel 40b and substantially equal to the crucible 90. As a feasible alternative, the heights of the metal barrels 40 may be made equal to or close to the height of the crucible 90. The number of the recesses 21 formed in the base 20 and the number of the metal barrels 40 mounted in the recesses 21 can be increased or decreased according to a desired result of heating.

The base 20 may be made of metal, thermal insulation ceramics, or other materials.

The metal barrels 40 are made of metal plates and the metal plates have thicknesses of 0.01 mm-10 cm. The metal plates are made of materials of aluminum, aluminum alloys, titanium, titanium alloys, or other metals having excellent thermal conductivities.

In summary, the present invention provides an evaporation source heating device, which comprises a plurality of metal barrels arranged between a heating element and a crucible. The plurality of metal barrels is mounted on a base. During heating, through a process of transmitting the heat from the heating element through the plurality of metal barrels in a step by step manner, the heat is transmitted to the crucible. Since the metal barrels have excellent properties of heat conduction, distribution of heat thereon is generally uniform, allowing the crucible to be uniformly heated and ensuring the result of evaporation deposition. Further, the number of the metal barrels can be increased or decreased according to practical needs in order to adjust the transfer and balance of temperature through the metal barrels and thus controlling the temperature difference of the crucible.

Based on the description given above, those having ordinary skills of the art may easily contemplate various changes and modifications of the technical solution and technical ideas of the present invention and all these changes and modifications are considered within the protection scope of right for the present invention.

What is claimed is:

1. An evaporation source heating device, comprising: a base, a housing coupled to the base, a heating element arranged inside the housing, a plurality of metal barrels arranged inside the heating element and mounted to the base, and a crucible arranged inside the metal barrels.

2. The evaporation source heating device as claimed in claim 1, wherein the base is received in the housing and the base comprises a plurality of recesses formed therein, the plurality of metal barrels being respectively mounted in the plurality of recesses.

3. The evaporation source heating device as claimed in claim 2, wherein the metal barrels are cylindrical and the recesses are circular recesses.

4. The evaporation source heating device as claimed in claim 3, wherein the circular recesses are concentric.

5. The evaporation source heating device as claimed in claim 1, wherein the metal barrels have heights that are substantially equal to or less than a height of the housing.

6. The evaporation source heating device as claimed in claim 1, wherein the base is made of a metal or a thermal insulation ceramic material.

7. The evaporation source heating device as claimed in claim 1, wherein the metal barrels are made of metal plates.

8. The evaporation source heating device as claimed in claim 7, wherein the metal plates have thicknesses of 0.01 mm-10 cm.

9. The evaporation source heating device as claimed in claim 7, wherein the metal plates are made of materials of aluminum, aluminum alloys, titanium, titanium alloys, or materials having excellent thermal conductivities.

10. The evaporation source heating device as claimed in claim 1, wherein the heating element comprises a heating resistance wire.

11. An evaporation source heating device, comprising: a base, a housing coupled to the base, a heating element arranged inside the housing, a plurality of metal barrels arranged inside the heating element and mounted to the base, and a crucible arranged inside the metal barrels;
wherein the base is received in the housing and the base comprises a plurality of recesses formed therein, the plurality of metal barrels being respectively mounted in the plurality of recesses;
wherein the metal barrels are cylindrical and the recesses are circular recesses;
wherein the circular recesses are concentric;
wherein the metal barrels have heights that are substantially equal to or less than a height of the housing;
wherein the base is made of a metal or a thermal insulation ceramic material;
wherein the metal barrels are made of metal plates;
wherein the metal plates have thicknesses of 0.01 mm-10 cm;
wherein the metal plates are made of materials of aluminum, aluminum alloys, titanium, titanium alloys, or materials having excellent thermal conductivities; and
wherein the heating element comprises a heating resistance wire.
